(19) United States
(12) Patent Application Publication
(10) Pub. No.: US 2024/0355046 A1
(43) Pub. Date: Oct. 24, 2024

(54) METHODS FOR GENERATING A PARTIAL THREE-DIMENSIONAL REPRESENTATION OF A PERSON

(71) Applicant: MPORT LTD, Crows Nest (AU)

(72) Inventors: Joon Wayn CHEONG, Crows Nest (AU); Weichen ZHANG, Crows Nest (AU); Yaqub JONMOHAMADI, Crows Nest (AU); Sergey KURCHATOV, Crows Nest (AU)

(21) Appl. No.: 18/684,278

(22) PCT Filed: Aug. 18, 2022
(86) PCT No.: PCT/AU2022/050916

§ 371 Date: Feb. 16, 2024

(30) Foreign Application Priority Data
Aug. 18, 2021 (AU) 2021902584

(51) Int. Cl. G06T 17/00; G06T 7/11; G06T 7/33; G06T 7/55

(52) U.S. Cl. CPC G06T 17/00; G06T 7/11; G06T 7/344; G06T 7/55; G06T 2207/10028; G06T 2207/30196; G06T 2210/12; G06T 2210/56

(57) ABSTRACT

Methods for generating a partial three-dimensional representation of a person are disclosed herein. In one aspect, a computer-implemented method comprises obtaining depth data of the person captured from a stationary depth camera scanning around the person; segmenting the depth data into a first segment; mapping the depth data of the first segment to a plurality of point clouds; performing pairwise registration on the point clouds of the first segment; segmenting the depth data into a second segment; mapping the depth data of the second segment to a plurality of point clouds; performing pairwise registration on the point clouds of the second segment; and merging the registered point clouds of the first and second segments to generate the partial 3D representation of the person.

### TECHNICAL FIELD

The present disclosure relates to methods for generating a partial three-dimensional (3D) representation of a person. The present disclosure also relates to methods for generating a 3D representation of an upper body of the person.

### BACKGROUND

Body size and shape information of a person is useful in a range of applications, including monitoring of health and/or fitness and selection and sizing of clothing. 3D models of body size and shape information allow people to easily visualise changes in their body over time. There are a variety of known hardware devices that can acquire such body and size information to enable the generation of digital 3D models representative of the body dimensions of a person. Such devices include depth cameras, which are capable of acquiring distance/depth information about scanned objects within their field of view.

Depth cameras are now becoming readily available in various personal portable devices, such as smartphones and tablets. However, despite their availability, there are limitations to the use of such depth cameras for generating 3D models representative of the body dimensions of a person. For example, it is impossible to generate a 3D model representative of a person's body from a single depth camera by capturing depth information only from one perspective. Known methodologies attempt to address this issue by capturing depth information while the depth camera traverses around the person or having multiple depth cameras located around the person. However, such methods either require multiple personnel to operate the depth camera(s) or the use of specialised scanning areas. Further, such methods rely on the scanned subject being stationary and typically do not correct or account for movement from the scanned subject during the scanning process, which may result in inaccuracies in the generated 3D model.

It is an object of the present disclosure to substantially overcome or ameliorate one or more of the above disadvantages, or at least provide a useful alternative.

### SUMMARY

In an aspect of the present disclosure, there is provided a computer-implemented method for generating a partial three-dimensional (3D) representation of a person, the method comprising:

obtaining depth data of the person captured from a stationary depth camera scanning around the person;

segmenting the depth data into a first segment, wherein the first segment is associated with a first region of the person;

mapping the depth data of the first segment to a plurality of point clouds;

performing pairwise registration on the point clouds of the first segment;

segmenting the depth data into a second segment, wherein the second segment is associated with a second region of the person;

mapping the depth data of the second segment to a plurality of point clouds;

performing pairwise registration on the point clouds of the second segment; and

merging the registered point clouds of the first and second segments to generate the partial 3D representation of the person.

Segmenting the depth data into the first segment may comprise:

identifying the depth data associated with the torso and head region of the person by box-bounding.

Mapping the depth data of the first segment to a plurality of point clouds may comprise:

filtering the depth data of the first segment; and

generating point clouds based on the filtered depth data of the first segment.

Pairwise registration on the point clouds of the first segment may be performed using the Interior Closest Point algorithm.

Pairwise registration on the point clouds of the first segment may comprise:

performing joint registration on the point clouds of the first segment.

Performing joint registration on the point clouds of the first segment may comprise:

initialising and selecting centroids of the depth data of the first segment;

applying the Joint Registration of Multiple Point Clouds (JRMPC) algorithm based on the depth data associated with the selected centroids.

Segmenting the depth data into the second segment may comprise:

identifying the depth data associated with left and right arms regions of the person by box-bounding.

Segmenting the depth data into the second segment further may comprise:

spatio-temporally segmenting the identified depth data with the left and right arm regions.

Segmentation of the depth data into the second segment may be based on the registered point clouds of the first segment.

Mapping the depth data of the second segment to a plurality of point clouds may comprise:

filtering the depth data of the second segment; and

generating point clouds based on the filtered depth data of the second segment.

Pairwise registration on the point clouds of the second segment may be performed using the Interior Closest Point algorithm.

The depth data may comprise a plurality of sequential depth frames. Each depth frame may comprise a plurality of depth pixels.

In another aspect of the present disclosure, there is provided a server for generating a partial three-dimensional (3D) representation of a person, the server comprising:

a network interface configured to communicate with a client device;

a memory or a storage device;

a processor coupled to the memory or the storage device and the network interface;

the memory including instructions executable by the processor such that the server is operable to:

obtain depth data of the person captured from a stationary depth camera scanning around the person;

segment the depth data into a first segment, wherein the first segment is associated with a first region of the person;

map the depth data of the first segment to a plurality of point clouds;

perform pairwise registration on the point clouds of the first segment;

segment the depth data into a second segment, wherein the second segment is associated with a second region of the person;

map the depth data of the second segment to a plurality of point clouds;

perform pairwise registration on the point clouds of the second segment; and

merge the registered point clouds of the first and second segments to generate the partial 3D representation of the person.

The server may be operable to segment the depth data into the first segment by:

identifying the depth data associated with the torso and head region of the person by box-bounding.

The server may be operable to map the depth data of the first segment to a plurality of point clouds by:

filtering the depth data of the first segment; and

generating point clouds based on the filtered depth data of the first segment.

The server may be operable to perform pairwise registration on the point clouds of the first segment using the Interior Closest Point algorithm.

The server may be operable to perform pairwise registration on the point clouds of the first segment by:

performing joint registration on the point clouds of the first segment.

Performing joint registration on the point clouds of the first segment may comprise:

initialising and selecting centroids of the depth data of the first segment;

applying the Joint Registration of Multiple Point Clouds (JRMPC) algorithm based on the depth data associated with the selected centroids.

The server may be operable to segment the depth data into the second segment by:

identifying the depth data associated with left and right arms regions of the person by box-bounding.

The server may be further operable to segment the depth data into the second segment by:

spatio-temporally segmenting the identified depth data with the left and right arm regions.

The server may be operable to segment the depth data into the second segment based on the registered point clouds of the first segment.

The server may be operable to map the depth data of the second segment to a plurality of point clouds by:

filtering the depth data of the second segment; and

generating point clouds based on the filtered depth data of the second segment.

The server may be operable to perform pairwise registration on the point clouds of the second segment using the Interior Closest Point algorithm.

The depth data may comprise a plurality of sequential depth frames. Each depth frame may comprise a plurality of depth pixels.

In a further aspect of the present disclosure, there is provided a computer-implemented method for generating a three-dimensional (3D) representation of an upper body of a person, the method comprising:

obtaining depth data of the upper body captured from a stationary depth camera scanning around the upper body;

segmenting the depth data into a plurality of segments, wherein each of the segments is associated with at least one region of the upper body;

in each segment, mapping the depth data therein to a plurality of point clouds;

in each segment, performing pairwise registration on the point clouds mapped therefrom; and

merging the registered point clouds of each segment to generate the 3D representation of the upper body.

In yet another aspect of the present disclosure, there is provided a server for generating a three-dimensional (3D) representation of an upper body of a person, the server comprising:

a network interface configured to communicate with a client device;

a memory or a storage device;

a processor coupled to the memory or the storage device and the network interface;

the memory including instructions executable by the processor such that the server is operable to:
obtain depth data of the upper body captured from a stationary depth camera scanning around the upper body;
segment the depth data into a plurality of segments, wherein each of the segments is associated with at least one region of the upper body;
in each segment, map the depth data therein to a plurality of point clouds;
in each segment, perform pairwise registration on the point clouds mapped therefrom; and
merge the registered point clouds of each segment to generate the 3D representation of the upper body.

### BRIEF DESCRIPTION OF DRAWINGS

Embodiments of the present disclosure will now be described hereinafter, by way of examples only, with reference to the accompanying drawings, in which:

FIG. 1 is a flow diagram showing an embodiment of a method of generating a virtual three-dimensional representation of an upper body of a person;

FIG. 2 is a schematic illustration of an embodiment of a client-server system;

FIG. 3 is a flow diagram showing an embodiment of a scanning process;

FIG. 4 is a flow diagram showing an embodiment of a method of generating a virtual three-dimensional representation of an upper body of a person after a scanning process;

FIG. 5 is a front view of a point cloud of the torso of the person in which centroids are initialised and selected during a joint registration process;

FIG. 6 is a flow diagram showing another embodiment of a method of generating a virtual three-dimensional representation of an upper body of a person after a scanning process;

FIG. 7 is a perspective view of a point cloud of the upper body of the person; and

FIG. 8 is a front view of a virtual 3D representation of the upper body of the person.

### DESCRIPTION OF EMBODIMENTS

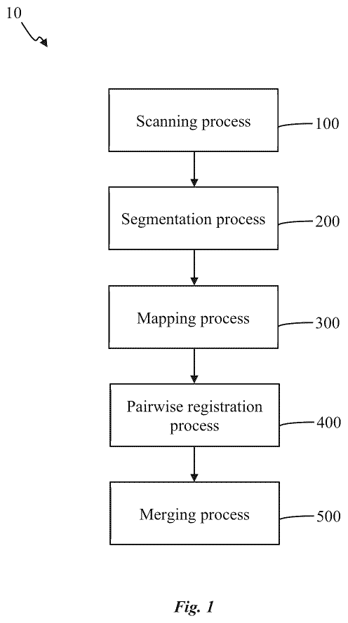

FIG. 1 shows an example method 10 of generating a virtual three-dimensional (3D) representation of an upper body of a person (referred to herein as a user). In the present disclosure, the term “upper body” is intended to refer to the top of the user's head down to the user's crotch. The method 10 generally comprises a scanning process 100, a segmentation process 200, a mapping process 300, a pairwise registration process 400 and a merging process 500, the implementation of which will be described hereinafter.

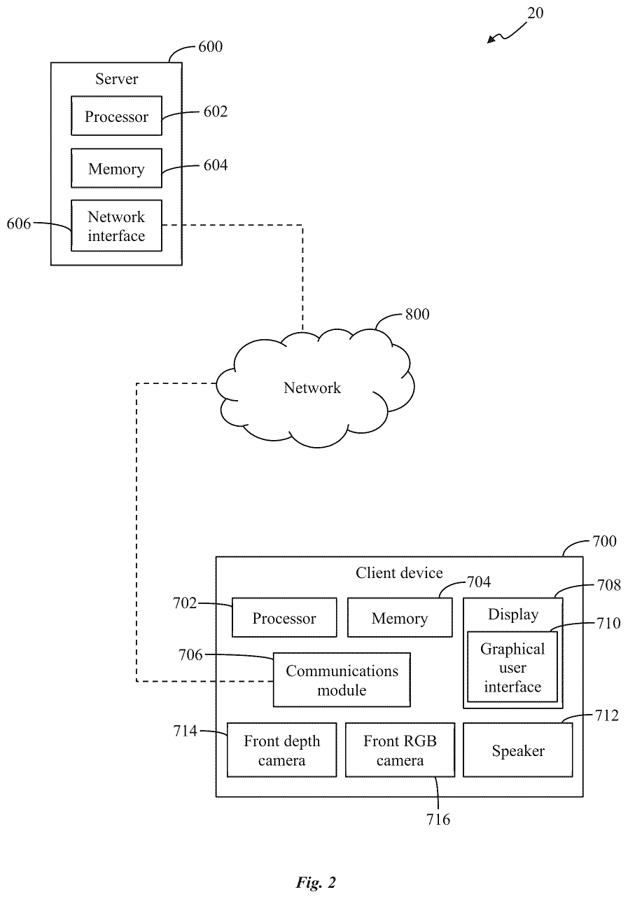

The method 10 may be implemented in a client-server system 20, as exemplified in FIG. 2. The system comprises a server 600 in the form of a server computer having a processor 602, a memory 604 and a network interface 606. The memory 604 is configured to store information and/or instructions for directing the processor 602. The processor 602 is configured to execute instructions, such as those stored in the memory 604. The network interface 606 is configured to communicate with a client device 700 over a network 800. The network 800 may be any network configured to operatively couple the client device 700 to the server 600. The network 800 may include the Internet and/or any cellular phone network (e.g. General Packet Radio Service (GPRS), Global System for Mobile Communication (GSM), Cellular Digital Packet Data (CDPD), Code Division Multiple Access (CDMA), Time Division Multiple Access (TDMA), Frequency Division Multiple Access (FDMA), Orthogonal Frequency Division Multiple Access (OFDMA), etc.).

In this embodiment, the client device 700 is in the form of a smartphone 700. The smartphone 700 comprises a processor 702 coupled to a memory 704, and a communications module 706 for communicating with the server 600 over the network 800. The smartphone 700 also comprises a front display 708 for displaying a Graphical User Interface (GUI) 710 to allow user interaction therewith, and one or more speakers 712.

In this embodiment, the smartphone 700 has a front depth camera 714 and a front Red, Green, Blue (RGB) camera 716. However, in other embodiments, the smartphone 700 may have a combined front Red, Green, Blue and Depth (RGB-D) camera. The front depth camera 714 is configured to capture depth data of one or more objects (e.g., the upper body of the user) in its field of view. The depth data comprises a plurality of sequential depth frames with each frame composed of a plurality of depth pixels. Each depth pixel is associated with a value representing the distance from the depth camera.

Implementation of the method 10 according to one or more embodiments will now be described in further detail below.

### Scanning Process

The method 10 begins with the scanning process 100, in which depth data of the upper body of the user is obtained from the front depth camera of the smartphone 700.

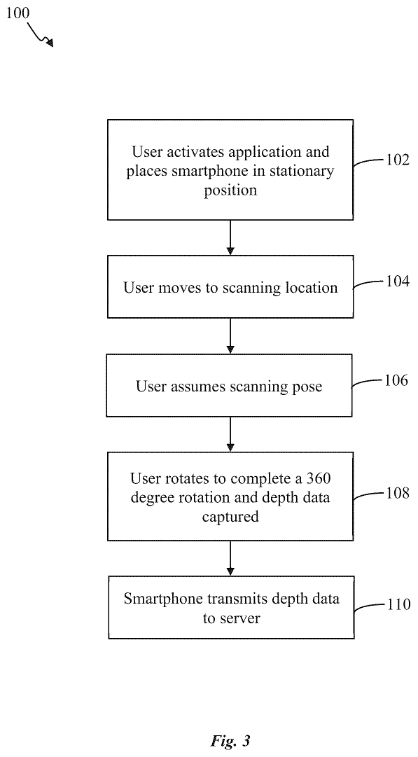

The scanning process 100 shown in FIG. 3 is described from the perspective of the user using the smartphone 700.

At step 102, the user activates an application on the smartphone 700 via the GUI 710 and places the smartphone 700 in a stationary upright position on or against a surface (e.g., on a stand or table). In this embodiment, the smartphone 700 is positioned such that the front depth camera 714 and the display 708 are both facing towards the user.

At step 104, the user moves away from the smartphone 700 to a scanning location. In the scanning location, the user's upper body is within the field of view of the front depth camera 714, and the boresight of the front depth camera 714 is aimed generally at the user's chest. Typically, the user will be about 60-100 cm from the smartphone 700 in the scanning location. The smartphone 700 may present live video footage, captured from the front RGB camera 716 of the smartphone 700, on the display 708 to assist the user in determining whether they are in the scanning location. Additionally or optionally, the smartphone 700 may present one or more augmented markers on the live video footage to indicate the field of view of the front depth camera 714 to further assist the user in determining whether they are in the scanning location. In some embodiments, the smartphone 700 may detect the user's location via the front depth camera 714 and/or the front RGB camera 716 of the smartphone 700 and determine whether the user is in the scanning location. If the user is not in the scanning location, the smartphone 700 may direct the user, by transmitting audio commands or notifications via the one or more speakers 712, for example, to the scanning location.

At step 106, the user then assumes a scanning pose. In the scanning pose, both of the user's hands are placed at the back of the user's head, preferably with their fingers interlocked. In some embodiments, the smartphone 700 may detect the user's pose via the front depth camera 714 and/or the front RGB camera 716 of the smartphone 700 and determine whether the user is in the scanning pose. If the user is not in the scanning pose, the smartphone 700 may instruct the user, by transmitting audio commands or notifications via the one or more speakers 712, for example, to amend their current pose.

Subsequently, at step 108, the user rotates in a clockwise direction to complete a 360 degree rotation, whilst remaining in the scanning location and in the scanning pose. In other embodiments, the user may rotate in an anti-clockwise direction to complete a 360 degree rotation. Concurrently, at step 108, the smartphone 700 operates the front depth camera 714 to periodically capture depth data of the user's upper body as the user rotates. Specifically, 25 depth frames per second of the user's upper body are captured by the depth camera 714. At step 110, the smartphone 700 transmits the captured depth data to the server 600 via the network 800 (Internet/cellular phone network) to complete the scanning process 100.

Although the above scanning steps are carried out with the user facing the front of the smartphone 700, it will be appreciated that in other embodiments the smartphone 700 may comprise a rear depth camera or a rear RGB-D camera such that the depth data of the user's upper body may be captured with the user facing the rear of the smartphone 700. In such embodiments, the smartphone 700 may transmit audio commands via the one or more speakers 712 to assist the user in determining whether they are in the scanning location and scanning pose.

### Segmentation Process

After the scanning process 100, the method 10 comprises a segmentation process 200 carried out by the server 600, in which the depth data is segmented into a plurality of segments. Each of the segments is associated with at least one anatomical part of the user's upper body. The anatomical parts of the user's upper body include the torso and head, the left arm (including the left hand), and the right arm (including the right hand).

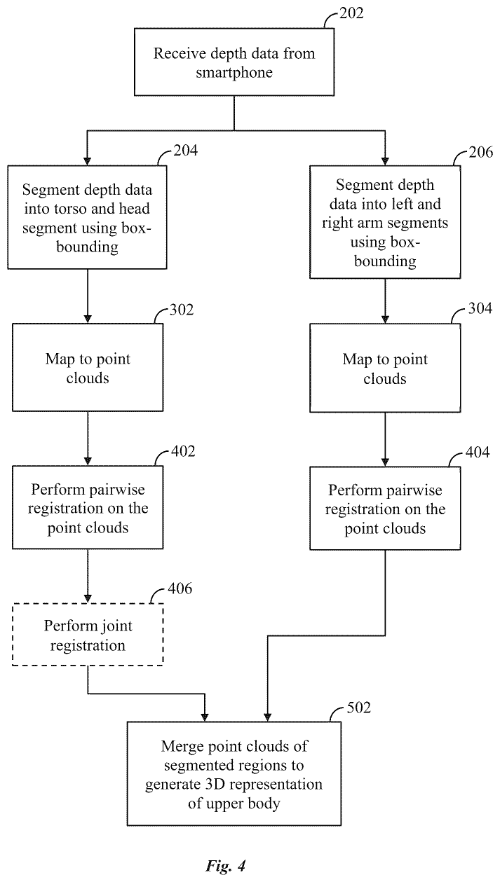

With reference to FIG. 4, at step 202, the server 600 receives the captured depth data from the smartphone 700 via the network 800.

At step 204, the server 600 identifies the depth pixels of each depth frame associated with the torso and head region of the user by using box-bounding and allocates those depth pixels into a segment (referred to herein as a torso and head segment). As the depth data is captured when the user is in the scanning location and the scanning pose, the horizontal span of the bounding box of the torso region is defined by applying the Density-Based Spatial Clustering of Applications with Noise (DB-SCAN) algorithm to the depth pixels, including connectivity checks of the depth pixels in the horizontal axis around the user's chest. The vertical span of the bounding box of the torso region is defined by the user's neck as the upper bound and the user's crotch as the lower bound. In this embodiment, image recognition techniques, such as Artificial Intelligence-based 3D feature recognition, is employed to detect the locations of the user's chest, neck and crotch. In other embodiments, a curvature-based implementation may be employed to detect the locations of the user's chest, neck and crotch. For example, the user's neck can be detected by seeking the smallest horizontal width, with the lowest width gradient in the vertical direction. The user's crotch may be detected using horizontal slicing from the ground up. In this regard, horizontal slicing would reveal two clusters of depth pixels pertaining to the left and right legs, and one cluster of depth pixels pertaining to the torso. The user's crotch may be identified as the point in which the two clusters of depth pixels transitions to one cluster of depth pixels.

At step 206, the server 600 identifies the depth pixels of each depth frame associated with the left and right arm regions of the user by using box-bounding and allocates those depth pixels into a respective segment (referred to herein as the left arm segment and the right arm segment). With the user assuming the scanning pose, box-bounding of the left and right arm regions can be achieved using image recognition techniques to detect the locations of the user's left and right arms. In another embodiment, box-bounding of the left and right arm regions may be inferred from depth pixels that are located outside the box-bound torso and head region.

Additionally, the server 600 performs spatio-temporal segmentation in order to identify two series of depth frames associated with the left arm and the right arm, as follows:
Left arm-The server 600 identifies depth frames associated with the first 180 degree rotation of the user.
Right arm-The server 600 identifies depth frames associated with the last 180 degree rotation of the user.

Spatio-temporal segmentation is performed to avoid issues with depth frames going out of view, resulting in temporal discontinuity.

The above spatio-temporal segmentation assumes that the user rotates in the clockwise direction. However, if the user rotates in the anti-clockwise, then the depth frames of the right arm would be associated with the first 180 degree rotation of the user and the depth frames of the left arm would be associated with the last 180 degree rotation of the user.

In another embodiment, at step 204 and step 206, the server 600 can utilise the Bertillon Anthropometry system to refine the box-bounding of the torso and head region and the left and right arm regions. For example, anthropometry measurements of various anatomical features may be derived from an inferred height of the user based on the captured depth data and/or a user-entered height on the application.

In other embodiments, the segmentation process 200 may also employ a machine learning unit for identifying various anatomical parts of the user. More specifically, a deep learning inference model derived from anatomy-labelled depth frames can be used. The machine learning unit may include supervised learning, unsupervised learning or semi-supervised learning. The machine learning unit may employ deep learning algorithms, including Convolutional Neural Network (CNN), Recurrent Neural Networks (RNNs), Long Short-Term Memory Networks (LSTMs), Stacked AutoEncoders, Deep Boltzmann Machine (DBM), or Deep Belief Networks (DBN). In particular, the Recurrent Neural Networks (RNNs) may provide connections between nodes to form a directed graph along a temporal sequence, which allows the Recurrent Neural Networks (RNNs) to exhibit temporal dynamic behaviour. The Recurrent Neural Networks (RNNs) may include two broad classes of networks with a similar general structure, i.e. a finite impulse and an infinite impulse, both of which exhibit temporal dynamic behaviour. A finite impulse recurrent network is a directed acyclic graph that can be unrolled and replaced with a strictly feedforward neural network, while an infinite impulse recurrent network is a directed cyclic graph that cannot be unrolled.

### Mapping Process

After the segmentation process 200, the method 10 also comprises a mapping process 300 carried out by the server 600, in which the depth pixels of each depth frame in each segment are mapped into a point cloud (steps 302 and 304 of FIG. 4). However, prior to doing so, the server 600 filters each segment to remove any depth pixel outliers therein. It is recognised that the depth data captured by the front depth camera 714 can contain depth pixel outliers. Such outliers are predominantly found around the edge of the user's upper body and may produce artefacts. To filter the segments, the server 600 categorises each depth pixel into a binary format as either a foreground pixel or a background pixel. The server 600 then applies the flood-fill algorithm to determine valid depth pixels connected to the user's upper body and excludes any floating outliers that are disconnected from the user's upper body. Subsequently, the server 600 applies an image processing technique known as ‘erosion’ to identify and remove depth pixel outliers.

For each segment, the server 600 then generates point clouds of the valid depth pixels for each depth frame. Specifically, each valid depth pixel is mapped to a point cloud in a local coordinate system, in which the x- and y-Cartesian coordinates of the point cloud correspond to the depth pixel's index and the z-Cartesian coordinate of the point cloud corresponds to the depth value of each valid depth pixel. The origin of the local coordinate system of the point cloud corresponds to the pinhole of the front depth camera 714, in which the z-axis is aligned with the boresight of the front depth camera 714 and the x-axis is along the horizontal.

The point clouds are then further processed to mitigate noise (downsampling), particularly Gaussian noise. Specifically, the server 600 performs selective spatio-temporal averaging at the edges of the user's upper body to normalise the point clouds.

### Pairwise Registration Process

Following the mapping process 300, the method 10 comprises a pairwise registration process 400 carried out by the server 600, in which pairwise registration is performed on the point clouds in each segment. Registration is the process of identifying the rotation and translation of one depth frame to another depth frame. In the case of pairwise registration in a particular segment, consecutive frames are used, i.e., frame one to frame two, frame two to frame three, frame three to frame four, etc. In this embodiment, the first depth frame 714 of the point cloud is used as the reference coordinate frame.

For the torso and head segment, at step 402 of FIG. 4, the server 600 performs pairwise registration on the point clouds of each pair of temporally consecutive depth frames using the Interior Closest Point (ICP) algorithm in a global coordinate system. The ICP minimises the difference between two sets of point clouds of the torso segment. This is repeated between all consecutive frames of the torso segment in order to obtain registrations of all frames relative to frame one.

For each of the left and right arm segments, at step 404 of FIG. 4, the server 600 performs pairwise registration on the point clouds of each pair of temporally consecutive depth frames using the ICP algorithm in a local coordinate system, assuming that the user rotates in the clockwise direction. With respect to the right arm segment, the sequence of pairwise registrations follows a reverse-time direction, in which: (N→N−1), (N−1→N−2), (N−2→N−3), where N is the number of the last frame. With respect to the left arm segment, the sequence of pairwise registrations follows a reverse-time direction. It will be appreciated that the time directions will be reversed if the user rotates in the anti-clockwise direction. Pairwise registration of the left and right arm segments in forward-time and reverse-time directions compensates for any movement in the arms as the user rotates in the scanning location and the scanning pose. By starting the sequence of pairwise registration from the first frame or last frame, pairwise registration would be improved, hence producing more consistent registration outcomes.

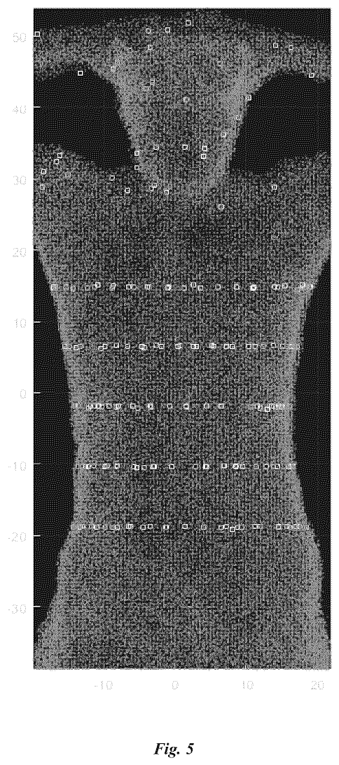

Additionally or optionally, at step 406 of FIG. 4, the server 600 can perform joint registration for the torso and head segment. In the joint registration process, all depth frames in the torso and head segment are simultaneously registered in an iterative optimisation process to obtain more refined registrations. Specifically, joint registration is performed by initialising and selecting centroids to emphasise certain anatomical parts (i.e., the user's torso) over other anatomical parts (e.g., the user's head and shoulders). FIG. 5 shows an example of sparse sample points of centroids being initialised for the user's head and shoulders and dense sample points of centroids in the form of rings being initialised for the user's torso. Each scatter point (corresponding to a depth pixel) is then associated with the closest centroids. Finally, the server 600 applies the Joint Registration of Multiple Point Clouds (JRMPC) algorithm to obtain a more accurate and consistent point cloud of the torso and head segment, including the armpits and the crotch of the user.

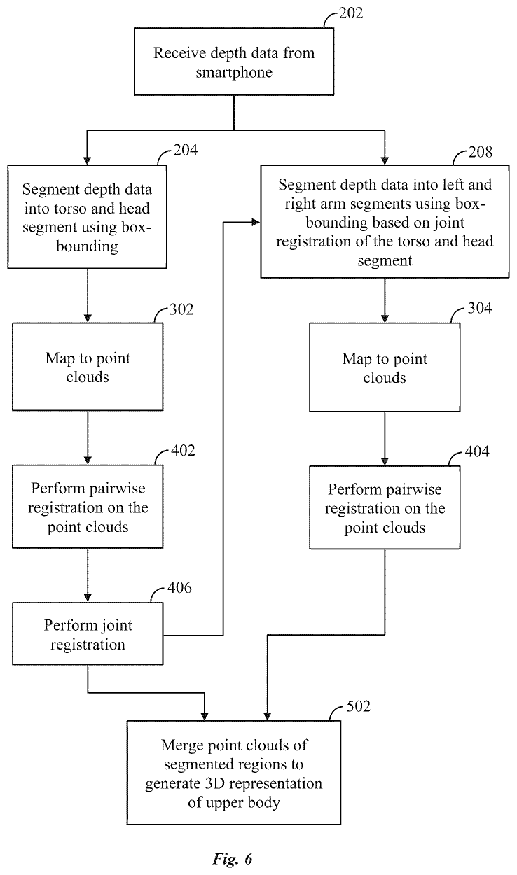

In another embodiment, as shown in FIG. 6, the refined registrations of the torso and head segment from step 406 can be utilised in conjunction with box-bounding to segment the left and right arm regions during their segmentation process at step 208. Refined registrations assist in improving box-bounding of the left and right arm regions.

In other embodiments, joint registration may be performed for a segment other than the torso segment (e.g., the left and/or right arm segments) to obtain more refined registrations of that segment. The refined registration of that segment can also be utilised to improve the box-bounding of another segment.

Merging Process

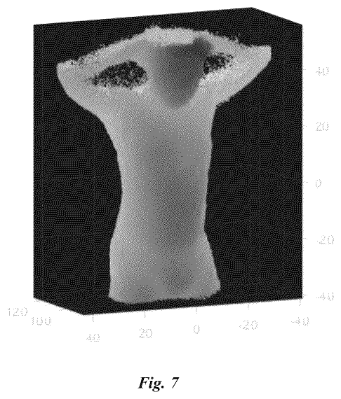

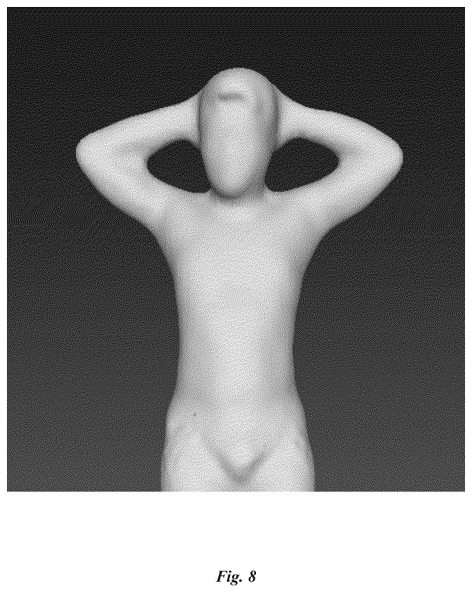

Following the mapping process 300, the method 10 comprises a merging process 500 carried out by the server 600 (step 502 of FIG. 4), in which the registered point clouds of the left arm, right arm and the head segments in the respective local coordinates systems are merged with the registered point cloud of the torso segment in the global coordinate system to generate a point cloud of the user's upper body, as illustrated in FIG. 7. The server 600 merges the registrations using the Poisson mesh generation method and removes outliers using a Gaussian probability distribution, resulting in a final virtual 3D representation of the user's upper body, as illustrated in FIG. 8.

According to the above described embodiments, the general principle employed is to divide the upper body based on known human anatomical parts of a person, in which segmentation boundaries occur at joins of these anatomical parts. To this end, the above described method segments the upper body of the person into individual parts, performs segmental registration for each of those individual parts, and merges each of the individual parts to obtain an upper body 3D representation. By recognising the upper body as multiple rigid anatomical parts, rather than a single body, the method 10 can substantially compensate for movement of a particular anatomical part relative to another, thus generating a more accurate 3D representation of the upper body of the person.

In this embodiment, the head and the torso of the user are considered as a single anatomical part. However, in other embodiments, the head of the user may be considered separate from the torso. In this regard, the server 600 may identify the depth pixels of each depth frame associated with the head region of the user and allocate those depth pixels into a head segment. Subsequently, the server 600 may map the depth pixels of each frame in the head segment into a point cloud, perform segmental registration for the head region, and merge the registered point cloud of the head segment with other segments to obtain an upper body 3D representation.

Although the above system 20 and the method 10 have been described by way of the client device 700 being in the form of a smartphone, it will be appreciated that the client device 700 may be embodied as any other device, so long as the client device 700 comprises a depth camera or a RGB-D camera that is configured to capture depth data for purposes of carrying out features of the present embodiments.

In other embodiments, the server 600 may be embodied as two or more server computers networked together. The two or more server computers may be connected by any form or medium of digital data communication (e.g., Local Area Network (LAN), Wide Area Network (WAN) and/or the Internet).

In other embodiments, it may not be necessary to generate a full 3D representation of the upper body of the person, but only of two or more anatomical parts of the person (e.g., a torso and a left arm). In this regard, the above system 20 and the method 10 may generate a partial 3D representation of a person based on the two or more anatomical parts of the person. In this regard, the server 600 may perform a segmentation process, a mapping process and a pairwise registration process for each anatomical part and the registered point cloud of each anatomical part may be merged together to generate the partial 3D representation of the person.

In general, it will be recognised that any processor used in the present disclosure may comprise a number of control or processing modules for controlling one or more features of the present disclosure and may also include one or more storage elements, for storing desired data. The modules and storage elements can be implemented using one or more processing devices and one or more data storage units, which modules and/or storage elements may be at one location or distributed across multiple locations and interconnected by one or more communication links. Processing devices may include computer systems such as desktop computers, laptop computers, tablets, smartphones, personal digital assistants and other types of devices, including devices manufactured specifically for the purpose of carrying out methods according to the present disclosure.

The features of the present embodiments described herein may be implemented in digital electronic circuitry, and/or in computer hardware, firmware, software, and/or in combinations thereof. Features of the present embodiments may be implemented in a computer program product tangibly embodied in an information carrier, such as a machine-readable storage device, and/or in a propagated signal, for execution by a programmable processor. Embodiments of the present method steps may be performed by a programmable processor executing a program of instructions to perform functions of the described implementations by operating on input data and generating output.

The features of the present embodiments described herein may be implemented in one or more computer programs that are executable on a programmable system including at least one programmable processor coupled to receive data and/or instructions from, and to transmit data and/or instructions to, a data storage system, at least one input device, and at least one output device. A computer program may include a set of instructions that may be used, directly or indirectly, in a computer to perform a certain activity or bring about a certain result. A computer program may be written in any form of programming language, including compiled or interpreted languages, and it may be deployed in any form, including as a stand-alone program or as a module, component, subroutine, or other unit suitable for use in a computing environment.

Suitable processors for the execution of a program of instructions may include, for example, both general and special purpose processors, and/or the sole processor or one of multiple processors of any kind of computer. Generally, a processor may receive instructions and/or data from a read only memory (ROM), or a random access memory (RAM), or both. Such a computer may include a processor for executing instructions and one or more memories for storing instructions and/or data.

Generally, a computer may also include, or be operatively coupled to communicate with, one or more mass storage devices for storing data files. Such devices include magnetic disks, such as internal hard disks and/or removable disks, magneto-optical disks, and/or optical disks. Storage devices suitable for tangibly embodying computer program instructions and/or data may include all forms of non-volatile memory, including for example semiconductor memory devices, such as EPROM, EEPROM, and flash memory devices, magnetic disks such as internal hard disks and removable disks, magneto-optical disks, and CD-ROM and DVD-ROM disks. The processor and the memory may be supplemented by, or incorporated in, one or more Application-Specific Integrated Circuits (ASICs).

It will be appreciated by persons skilled in the art that numerous variations and/or modifications may be made to the above-described embodiments, without departing from the broad general scope of the present disclosure. The present embodiments are, therefore, to be considered in all respects as illustrative and not restrictive.

1. A computer-implemented method for generating a partial three-dimensional (3D) representation of a person, the method comprising:
obtaining depth data of the person captured from a stationary depth camera scanning around the person;
segmenting the depth data into a first segment, wherein the first segment is associated with a first region of the person;
mapping the depth data of the first segment to a plurality of point clouds;
performing pairwise registration on the point clouds of the first segment;
segmenting the depth data into a second segment, wherein the second segment is associated with a second region of the person;
mapping the depth data of the second segment to a plurality of point clouds;
performing pairwise registration on the point clouds of the second segment; and
merging the registered point clouds of the first and second segments to generate the partial 3D representation of the person.

2. The computer-implemented method according to claim 1, wherein segmenting the depth data into the first segment comprises:
identifying the depth data associated with the torso and head region of the person by box-bounding.

3. The computer-implemented method according to claim 2, wherein mapping the depth data of the first segment to a plurality of point clouds comprises:
filtering the depth data of the first segment; and
generating point clouds based on the filtered depth data of the first segment.

4. The computer-implemented method according to claim 3, wherein pairwise registration on the point clouds of the first segment is performed using the Interior Closest Point algorithm.

5. The computer-implemented method according to claim 1, wherein pairwise registration on the point clouds of the first segment comprises:
performing joint registration on the point clouds of the first segment.

6. The computer-implemented method according to claim 5, wherein performing joint registration on the point clouds of the first segment comprises:
initialising and selecting centroids of the depth data of the first segment;
applying the Joint Registration of Multiple Point Clouds (JRMPC) algorithm based on the depth data associated with the selected centroids.

7. The computer-implemented method according to claim 1, wherein segmenting the depth data into the second segment comprises:
identifying the depth data associated with left and right arms regions of the person by box-bounding.

8. The computer-implemented method according to claim 7, wherein segmenting the depth data into the second segment further comprises:
spatio-temporally segmenting the identified depth data with the left and right arm regions.

9. The computer-implemented method according to claim 1, wherein segmentation of the depth data into the second segment is based on the registered point clouds of the first segment.

10. The computer-implemented method according to claim 7, wherein mapping the depth data of the second segment to a plurality of point clouds comprises:
filtering the depth data of the second segment; and
generating point clouds based on the filtered depth data of the second segment.

11. The computer-implemented method according to claim 7, wherein pairwise registration on the point clouds of the second segment is performed using the Interior Closest Point algorithm.

12. The computer-implemented method according to claim 1, wherein the depth data comprises a plurality of sequential depth frames, each depth frame comprising a plurality of depth pixels.

13. A server for generating a partial three-dimensional (3D) representation of a person, the server comprising:
a network interface configured to communicate with a client device;
a memory or a storage device;
a processor coupled to the memory or the storage device and the network interface;
the memory or storage device including instructions executable by the processor such that the server is operable to:
obtain depth data of the person captured from a stationary depth camera scanning around the person;
segment the depth data into a first segment, wherein the first segment is associated with a first region of the person;
map the depth data of the first segment to a plurality of point clouds;
perform pairwise registration on the point clouds of the first segment;
segment the depth data into a second segment, wherein the second segment is associated with a second region of the person;
map the depth data of the second segment to a plurality of point clouds;
perform pairwise registration on the point clouds of the second segment; and
merge the registered point clouds of the first and second segments to generate the partial 3D representation of the person.

14. The server according to claim 13, wherein the server is operable to segment the depth data into the first segment by:
identifying the depth data associated with the torso and head region of the person by box-bounding.

15. The server according to claim 14, wherein the server is operable to map the depth data of the first segment to a plurality of point clouds by:
filtering the depth data of the first segment; and
generating point clouds based on the filtered depth data of the first segment.

16. The server according to claim 15, wherein the server is operable to perform pairwise registration on the point clouds of the first segment using the Interior Closest Point algorithm.

17. The server according to claim 13, wherein the server is operable to perform pairwise registration on the point clouds of the first segment by:
performing joint registration on the point clouds of the first segment.

18. The server according to claim 17, wherein performing joint registration on the point clouds of the first segment comprises:
initialising and selecting centroids of the depth data of the first segment;
applying the Joint Registration of Multiple Point Clouds (JRMPC) algorithm based on the depth data associated with the selected centroids.

19. The server according to claim 13, wherein the server is operable to segment the depth data into the second segment by:
identifying the depth data associated with left and right arms regions of the person by box-bounding.

20. The server according to claim 19, wherein the server is further operable to segment the depth data into the second segment by:
spatio-temporally segmenting the identified depth data with the left and right arm regions.

21. The server according to claim 13, wherein the server is operable to segment the depth data into the second segment based on the registered point clouds of the first segment.

22. The server according to claim 19, wherein the server is operable to map the depth data of the second segment to a plurality of point clouds by:
filtering the depth data of the second segment; and
generating point clouds based on the filtered depth data of the second segment.

23. The server according to claim 19, wherein the server is operable to perform pairwise registration on the point clouds of the second segment using the Interior Closest Point algorithm.

24. The server according to claim 13, wherein the depth data comprises a plurality of sequential depth frames, each depth frame comprising a plurality of depth pixels.

25. A computer-implemented method for generating a three-dimensional (3D) representation of an upper body of a person, the method comprising:
obtaining depth data of the upper body captured from a stationary depth camera scanning around the upper body;
segmenting the depth data into a plurality of segments, wherein each of the segments is associated with at least one region of the upper body;
in each segment, mapping the depth data therein to a plurality of point clouds;
in each segment, performing pairwise registration on the point clouds mapped therefrom; and
merging the registered point clouds of each segment to generate the 3D representation of the upper body.

26. A server for generating a three-dimensional (3D) representation of an upper body of a person, the server comprising:
a network interface configured to communicate with a client device;
a memory or a storage device;
a processor coupled to the memory or the storage device and the network interface;
the memory or storage device including instructions executable by the processor such that the server is operable to:
obtain depth data of the upper body captured from a stationary depth camera scanning around the upper body;
segment the depth data into a plurality of segments, wherein each of the segments is associated with at least one region of the upper body;
in each segment, map the depth data therein to a plurality of point clouds;
in each segment, perform pairwise registration on the point clouds mapped therefrom; and
merge the registered point clouds of each segment to generate the 3D representation of the upper body.
